(19) United States
(12) Patent Application Publication
(10) Pub. No.: US 2024/0324296 A1
(43) Pub. Date: Sep. 26, 2024

(54) DISPLAY APPARATUS

(71) Applicant: Samsung Display Co., LTD., Yongin-si (KR)

(72) Inventors: Seonhwa CHOI, Yongin-si (KR); Youngjun KIM, Yongin-si (KR); Dongkyun SEO, Yongin-si (KR); Hyunyoung JUNG, Yongin-si (KR)

(21) Appl. No.: 18/380,969

(22) Filed: Oct. 17, 2023

(30) Foreign Application Priority Data
Mar. 24, 2023 (KR) 10-2023-0039108
Apr. 28, 2023 (KR) 10-2023-0056591

(51) Int. Cl. H10K 59/122; H10K 59/12

(52) U.S. Cl. CPC H10K 59/122; H10K 59/1201

(57) ABSTRACT

A display apparatus includes a first sub-pixel electrode arranged in a sub-pixel area, a conductive bank layer disposed on the first sub-pixel electrode, including a first opening, a first conductive layer and a second conductive layer, wherein the first opening overlaps the first sub-pixel electrode, a first intermediate layer disposed on the first sub-pixel electrode through the first opening, a first opposite electrode disposed on the first intermediate layer, an insulating layer disposed between the conductive bank layer and an edge of the first sub-pixel electrode in a non-sub-pixel area around the sub-pixel area, and an organic layer including an opening overlapping the first opening of the conductive bank layer, and including a first organic material portion overlapping the insulating layer in the non-sub-pixel area.

This application claims priority to Korean Patent Application No. 10-2023-0039108, filed on Mar. 24, 2023 and Korean Patent Application No. 10-2023-0056591, filed on Apr. 28, 2023, and all the benefits accruing therefrom under 35 U.S.C. § 119, the contents of which in their entirety are herein incorporated by reference.

### BACKGROUND

### 1. Field

One or more embodiments relate to a display apparatus, and more particularly, to a structure of a display apparatus.

### 2. Description of the Related Art

A display apparatus visually displays data. The display apparatus may include a substrate divided into a display area and a non-display area. A plurality of pixels may be included in the display area. In addition, a thin-film transistor and a sub-pixel electrode electrically connected to the thin-film transistor may be provided in the display area, wherein each of the thin-film transistor and the sub-pixel electrode corresponds to each of the pixels. In addition, an emission layer may be provided in the display area to correspond to each of the sub-pixel electrodes and an opposite electrode may be provided in the display area, wherein the opposite electrode is commonly provided to the pixels. Various wirings, a driver, a controller, and the like configured to transfer electrical signals to the display area may be provided in the non-display area.

Recently, the usage of display apparatuses has diversified. Accordingly, various attempts have been made to design a display apparatus with an improved quality.

### SUMMARY

One or more embodiments include a display apparatus capable of implementing images of excellent quality with a reduced external light reflectivity. However, such a technical objective is just an example, and the disclosure is not limited thereto.

According to one or more embodiments, a display apparatus includes a first sub-pixel electrode arranged in a sub-pixel area, a conductive bank layer disposed on the first sub-pixel electrode, including a first opening, a first conductive layer and a second conductive layer, wherein the first opening overlaps the first sub-pixel electrode, a first intermediate layer disposed on the first sub-pixel electrode through the first opening, a first opposite electrode disposed on the first intermediate layer, an insulating layer disposed between the conductive bank layer and an edge of the first sub-pixel electrode in a non-sub-pixel area around the sub-pixel area, and an organic layer including an opening overlapping the first opening of the conductive bank layer, and including a first organic material portion overlapping the insulating layer in the non-sub-pixel area.

In an embodiment, the conductive bank layer may include a first hole arranged in the non-sub-pixel area, and the first organic material portion of the organic layer may be present in the first hole.

In an embodiment, the conductive bank layer may further include a second hole arranged in the non-sub-pixel area and disposed adjacent to the first hole, and a second organic material portion of the organic layer may be present inside the second hole, wherein the first organic material portion and the second organic material portion may be spaced apart from each other in a plan view.

In an embodiment, the first hole of the conductive bank layer may pass through the conductive bank layer, and the first organic material portion of the organic layer may be in direct contact with an upper surface of the insulating layer through the first hole.

In an embodiment, a bottom surface of the organic layer may be in direct contact with an upper surface of the second conductive layer.

In an embodiment, the second conductive layer of the conductive bank layer may be disposed on an upper surface of the first conductive layer, and the second conductive layer may include a tip protruding from a point at which a lateral surface of the first conductive layer facing the first opening meets a bottom surface of the second conductive layer.

In an embodiment, the display apparatus may further include a first dummy intermediate layer disposed on the tip and including a same material as a material of the first intermediate layer, and a first dummy opposite electrode disposed on the first dummy intermediate layer and including a same material as a material of the first opposite electrode.

In an embodiment, the organic layer may include an organic insulating material.

In an embodiment, the organic layer may include black pigment.

According to one or more embodiments, a display apparatus includes a first sub-pixel electrode and a second sub-pixel electrode disposed adjacent to each other, a conductive bank layer including a first opening overlapping the first sub-pixel electrode, and a second opening overlapping the second sub-pixel electrode, and including a first conductive layer and a second conductive layer on the first conductive layer, a first intermediate layer disposed on the first sub-pixel electrode through the first opening, a first opposite electrode disposed on the first intermediate layer, a second intermediate layer disposed on the second sub-pixel electrode through the second opening, a second opposite electrode disposed on the second intermediate layer, an insulating layer overlapping an edge of the first sub-pixel electrode and an edge of the second sub-pixel electrode and disposed under the conductive bank layer in a non-sub-pixel area to be disposed between the first sub-pixel electrode and the second sub-pixel electrode, and an organic layer including an opening overlapping the first opening, an opening overlapping the second opening, and a first organic material portion arranged in the non-sub-pixel area.

In an embodiment, the conductive bank layer may include a first hole arranged in the non-sub-pixel area, and at least a portion of the first organic material portion may be present inside the first hole.

In an embodiment, a bottom surface of the organic layer may be in direct contact with an upper surface of the second conductive layer.

In an embodiment, a depth of the first hole may be less than a thickness of the conductive bank layer.

a depth of the first hole may be equal to a thickness of the conductive bank layer, and at least a portion of the organic material portion may be in direct contact with an upper surface of the insulating layer through the first hole.

In an embodiment, a portion of the second conductive layer of the conductive bank layer may include a tip protruding to the first opening from a point at which a lateral surface of the first conductive layer facing the first opening meets a bottom surface of the second conductive layer, and another portion of the second conductive layer of the conductive bank layer may include a tip protruding to the second opening from a point at which a lateral surface of the first conductive layer facing the second opening meets a bottom surface of the second conductive layer.

In an embodiment, the display apparatus may further include a first dummy intermediate layer formed on the tip protruding to the first opening and including a same material as a material of the first intermediate layer, a first dummy opposite electrode formed on the first dummy intermediate layer and including a same material as a material of the first opposite electrode, a second dummy intermediate layer formed on the tip protruding to the second opening and including a same material as a material of the second intermediate layer, and a second dummy opposite electrode formed on the second dummy intermediate layer and including a same material as a material of the second opposite electrode.

In an embodiment, the conductive bank layer may further include a second hole disposed adjacent to the first hole, wherein the first hole may be spatially separated from the second hole.

In an embodiment, the organic layer may further include a second organic material portion, wherein at least a portion of the second organic material portion is present in the second hole, and wherein the first organic material portion and the second organic material portion may be spaced apart from each other.

In an embodiment, the organic layer may include an organic insulating material.

In an embodiment, the organic layer may include black pigment.

### BRIEF DESCRIPTION OF THE DRAWINGS

The above and other aspects, features, and advantages of embodiments of the invention will be more apparent from the following description taken in conjunction with the accompanying drawings, in which:

FIG. 1A is a schematic perspective view of a display apparatus, according to an embodiment;

FIG. 1B is an enlarged plan view of a portion of a display area of FIG. 1A, according to an embodiment;

FIG. 2 is a cross-sectional view of the display apparatus, according to an embodiment;

FIG. 3 is a cross-sectional view of the display apparatus, according to an embodiment;

FIG. 4 is a cross-sectional view of the display apparatus, according to an embodiment;

FIG. 5 is a cross-sectional view of the display apparatus, according to an embodiment;

FIG. 6 is a cross-sectional view of the display apparatus according to an embodiment;

FIG. 7A is a schematic plan view of the display apparatus, according to an embodiment;

FIG. 7B is a schematic plan view of the display apparatus, according to an embodiment;

FIG. 8A is a schematic cross-sectional view showing states corresponding to a process of manufacturing a display apparatus, according to an embodiment;

FIG. 8B is a schematic cross-sectional view showing states corresponding to a process of manufacturing a display apparatus, according to an embodiment;

FIG. 8C is a schematic cross-sectional view showing states corresponding to a process of manufacturing a display apparatus, according to an embodiment;

FIG. 8D is a schematic cross-sectional view showing states corresponding to a process of manufacturing a display apparatus, according to an embodiment;

FIG. 8E is a schematic cross-sectional view showing states corresponding to a process of manufacturing a display apparatus, according to an embodiment;

FIG. 8F is a schematic cross-sectional view showing states corresponding to a process of manufacturing a display apparatus, according to an embodiment;

FIG. 8G is a schematic cross-sectional view showing states corresponding to a process of manufacturing a display apparatus, according to an embodiment;

FIG. 9A is a schematic cross-sectional view showing states corresponding to a process of manufacturing a display apparatus, according to an embodiment;

FIG. 9B is a schematic cross-sectional view showing states corresponding to a process of manufacturing a display apparatus, according to an embodiment;

FIG. 9C is a schematic cross-sectional view showing states corresponding to a process of manufacturing a display apparatus, according to an embodiment;

FIG. 9D is a schematic cross-sectional view showing states corresponding to a process of manufacturing a display apparatus, according to an embodiment;

FIG. 9E is a schematic cross-sectional view showing states corresponding to a process of manufacturing a display apparatus, according to an embodiment;

FIG. 9F is a schematic cross-sectional view showing states corresponding to a process of manufacturing a display apparatus, according to an embodiment;

FIG. 9G is a schematic cross-sectional view showing states corresponding to a process of manufacturing a display apparatus, according to an embodiment;

FIG. 10A is a schematic cross-sectional view showing states corresponding to a process of manufacturing a display apparatus, according to an embodiment;

FIG. 10B is a schematic cross-sectional view showing states corresponding to a process of manufacturing a display apparatus, according to an embodiment;

FIG. 10C is a schematic cross-sectional view showing states corresponding to a process of manufacturing a display apparatus, according to an embodiment;

FIG. 10D is a schematic cross-sectional view showing states corresponding to a process of manufacturing a display apparatus, according to an embodiment;

FIG. 10E is a schematic cross-sectional view showing states corresponding to a process of manufacturing a display apparatus, according to an embodiment; and

FIG. 10F is a schematic cross-sectional view showing states corresponding to a process of manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the invention. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the invention allows for various changes and numerous embodiments, certain embodiments will be illustrated in the drawings and described in the written description. Effects and features of the invention, and methods for achieving them will be clarified with reference to embodiments described below in detail with reference to the drawings. However, the invention is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the invention is not necessarily limited thereto.

In the case where a certain embodiment may be implemented differently, a specific process order may be performed in the order different from the described order. As an example, two processes successively described may be simultaneously performed substantially and performed in the opposite order.

In the present specification, “A and/or B” means A or B, or A and B. In the present specification, “at least one of A and B” means A or B, or A and B.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

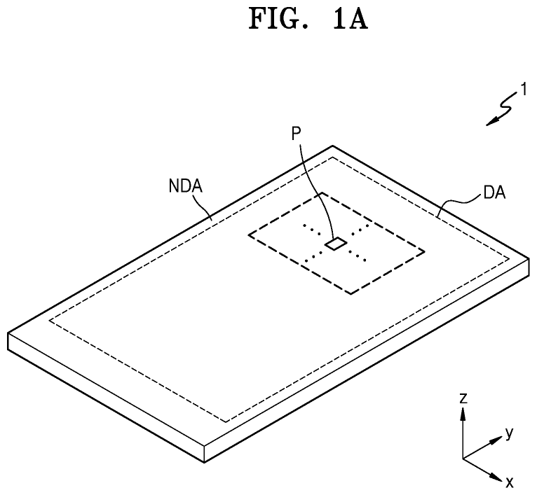

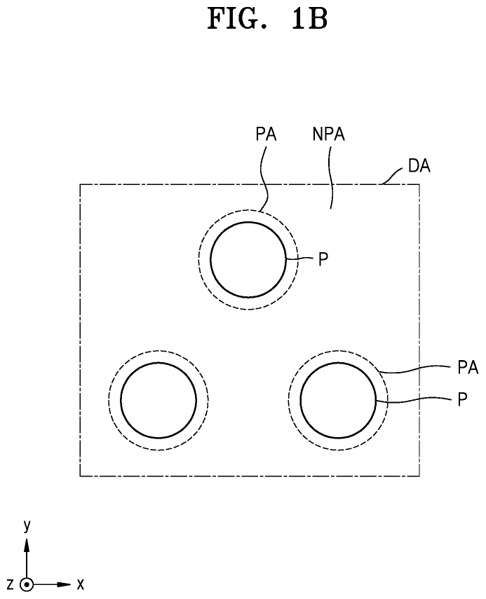

FIG. 1A is a schematic perspective view of a display apparatus 1, according to an embodiment.

In an embodiment and referring to FIG. 1A, the display apparatus 1 may include a display area DA and a non-display area NDA outside the display area DA. The display area DA may be configured to display images through sub-pixels P arranged in the display area DA. The non-display area NDA is arranged outside the display area DA and does not display images. The non-display area NDA may surround the display area DA entirely. A driver and the like configured to provide electrical signals and/or power to the display area DA may be arranged in the non-display area NDA. A pad may be arranged in the non-display area NDA, wherein the pad is a region to which electronic elements and/or a printed circuit board may be electrically connected.

In an embodiment, although FIG. 1A shows that the display area DA is a polygon (e.g., a quadrangle) in which a length thereof in an x direction is less than a length thereof in a y direction, the display area DA may be a polygon (e.g., a quadrangle) in which a length thereof in the y direction is less than a length thereof in the x direction in another embodiment. Although FIG. 1A shows the display area DA is an approximately quadrangle, the embodiment is not limited thereto. As another embodiment, the display area DA may have various shapes such as an N-gon (where N is a natural number of 3 or more), a circle, or an ellipse. Although it is shown in FIG. 1A that the display area DA has a shape in which a corner of the display area DA includes a vertex at which a straight line meets a straight line, the display area DA may have a polygon in which a corner portion is curved in another embodiment.

FIG. 1B is an enlarged plan view of a portion of the display area DA of FIG. 1A, according to an embodiment.

In an embodiment and referring to FIG. 1B, the display area DA may include a sub-pixel area PA in which sub-pixels P are arranged, and a non-sub-pixel area NPA. The sub-pixel area PA is a region in which the sub-pixels P are arranged. A light-emitting diode including an overlapping structure of a sub-pixel electrode, an intermediate layer, and an opposite electrode described below may be arranged in the sub-pixel area PA. The non-sub-pixel area NPA may be arranged around the sub-pixel area PA and may surround each sub-pixel area PA entirely.

Although it is shown in FIG. 1B that the shape of the sub-pixel area PA is circular, the embodiment is not limited thereto. In another embodiment, the sub-pixel area PA may have various shapes such as an N-gon (where N is a natural number of 3 or more) or an ellipse.

Hereinafter, for convenience of description, although the case where the display apparatus 1 is a smartphone is described, the display apparatus 1 according to an embodiment is not limited thereto. In an embodiment, the display apparatus 1 is applicable to various products including televisions, notebook computers, monitors, advertisement boards, Internet of things (IoTs) as well as portable electronic apparatuses including mobile phones, smartphones, tablet personal computers (PCs), mobile communication terminals, electronic organizers, electronic books, portable multimedia players (PMPs), navigations, and/or ultra mobile personal computers (UMPCs). In addition, the display apparatus 1 according to an embodiment is applicable to wearable devices including smartwatches, watchphones, glasses-type displays, and/or head-mounted displays (HMDs). In addition, in an embodiment, the display apparatus 1 is applicable to a display screen in instrument panels for automobiles, center fascias for automobiles, and/or center information displays (CIDs) arranged on a dashboard, room mirror displays that replace side mirrors of automobiles, and/or displays of an entertainment system arranged on the backside of front seats for backseat passengers in automobiles.

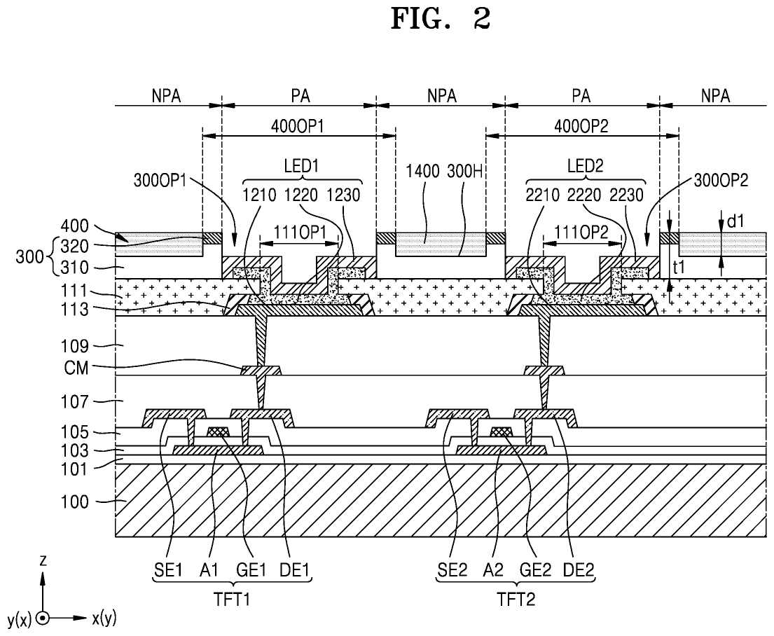

FIG. 2 is a schematic cross-sectional view of the display apparatus 1, according to an embodiment.

Referring to FIG. 2, the display apparatus 1, according to an embodiment, includes light-emitting diodes disposed over a substrate 100 and respectively corresponding to the sub-pixels P (see FIG. 1B) described with reference to FIG. 1B, wherein the light-emitting diodes include, for example, a first light-emitting diode LED1 and a second light-emitting diode LED2. The light-emitting diodes may each be arranged in the sub-pixel area PA. With regard to this, it is shown in FIG. 2 that the first light-emitting diode LED1 and the second light-emitting diode LED2 each are arranged in the sub-pixel area PA. Each of the first light-emitting diode LED1 and the second light-emitting diode LED2 may include the sub-pixel electrode, the intermediate layer, and the opposite electrode disposed on the intermediate layer, wherein the intermediate layer is disposed on the sub-pixel electrode and includes an organic emission layer. The first light-emitting diode LED1 and the second light-emitting diode LED2 may be respectively electrically connected to a first thin-film transistor TFT1 and a second thin-film transistor TFT2 disposed on the substrate 100.

In an embodiment, the substrate 100 may include glass or polymer resin. The substrate 100 may have a structure in which a base layer including polymer resin and an inorganic barrier layer including an inorganic insulating material are stacked. The polymer resin may include polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose tri acetate (TAC), and/or cellulose acetate propionate (CAP).

In an embodiment, a buffer layer 101 may be disposed on the upper surface of the substrate 100. The buffer layer 101 may prevent impurities from penetrating a semiconductor layer of a transistor. The buffer layer 101 may include an inorganic insulating material such as silicon nitride, silicon oxynitride, and/or silicon oxide, and include a single layer or a multi-layer including the above inorganic insulating materials.

In an embodiment, the first and second thin-film transistors TFT1 and TFT2 may be disposed on the buffer layer 101.

In an embodiment, the first and second thin-film transistors TFT1 and TFT2 may include active layers A1 and A2, respectively, gate electrodes GE1 and GE2, respectively, source electrodes SE1 and SE2, respectively, and drain electrodes DE1 and DE2, respectively, wherein the active layers A1 and A2 include amorphous silicon, polycrystalline silicon, an oxide semiconductor, and/or a semiconductor material such as an organic semiconductor material, the gate electrodes GE1 and GE2 are insulated from the active layers A1 and A2, respectively, and the source electrodes SE1 and SE2 and drain electrodes DE1 and DE2 are respectively electrically connected to the active layers A1 and A2. The gate electrodes GE1 and GE2 are disposed over the active layers A1 and A2, respectively. The source electrodes SE1 and SE2 and the drain electrodes DE1 and DE2 are electrically connected according to signals applied to the gate electrodes GE1 and GE2, respectively. The gate electrodes GE1 and GE2 may include at least one of aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), and include a single layer or a multi-layer by taking into account adhesion with adjacent layers, surface flatness of stacked layers, workability, and the like.

In an embodiment, to secure insulation between the active layers A1 and A2 and the gate electrodes GE1 and GE2, a gate insulating layer 103 may be disposed between the active layers A1 and A2 and the gate electrodes GE1 and GE2, respectively. The gate insulating layer 103 may include an inorganic insulating material such as silicon oxide, silicon nitride and/or silicon oxynitride. In addition, an interlayer insulating layer 105 may be disposed on the gate electrodes GE1 and GE2, wherein the interlayer insulating layer 105 includes an inorganic insulating material such as silicon oxide, silicon nitride, and/or silicon oxynitride. The source electrodes SE1 and SE2 and the drain electrodes DE1 and DE2 may be disposed on the interlayer insulating layer 105. The source electrodes SE1 and SE2 and the drain electrodes DE1 and DE2 may be respectively electrically connected to the active layers A1 and A2 through contact holes formed in the gate insulating layer 103 and the interlayer insulating layer 105.

In an embodiment, a first organic insulating layer 107 may be disposed on the interlayer insulating layer 105. The first organic insulating layer 107 may include an organic insulating material such as acryl, benzocyclobutene (BCB), polyimide (PI), or hexamethyldisiloxane (HMDSO).

In an embodiment, a connection metal CM may be disposed on the first organic insulating layer 107. The connection metal CM may include aluminum (Al), copper (Cu), and/or titanium (Ti), and include a single layer or a multi-layer including the above materials.

In an embodiment, a second organic insulating layer 109 may be disposed between the connection metal CM and the sub-pixel electrode, for example, first and second sub-pixel electrodes 1210 and 2210, respectively. The second organic insulating layer 109 may include an organic insulating material such as acryl, benzocyclobutene (BCB), polyimide (PI), or hexamethyldisiloxane (HMDSO). According to an embodiment described with reference to FIG. 2, although the first and second thin-film transistors TFT1 and TFT2, respectively, are respectively electrically connected to the first and second sub-pixel electrodes 1210 and 2210 through the connection metal CM, the connection metal CM may be omitted and one organic insulating layer may be disposed between the first and second thin-film transistors TFT1 and TFT2, respectively, and the first and second sub-pixel electrodes 1210 and 2210, respectively, in another embodiment. Alternatively, three or more organic insulating layers may be disposed between the first and second thin-film transistors TFT1 and TFT2, respectively, and the first and second sub-pixel electrodes 1210 and 2210, respectively, and the first and second thin-film transistors TFT1 and TFT2, respectively, may be respectively electrically connected to the first and second sub-pixel electrodes 1210 and 2210 through a plurality of connection metals.

In an embodiment, the sub-pixel electrodes, for example, the first and second sub-pixel electrodes 1210 and 2210, respectively, may be disposed on the second organic insulating layer 109. The first and second sub-pixel electrode 1210 and 2210, respectively, may be formed to be a (semi) transparent electrode or formed to be a reflective electrode. In the case where the first and second sub-pixel electrode 1210 and 2210, respectively, include a (semi) transparent electrode, the first and second sub-pixel electrode 1210 and 2210, respectively, may include indium tin oxide (ITO), indium zinc oxide (IZO), zinc oxide (ZnO), indium oxide (In₂O₃), indium gallium oxide (IGO), and/or aluminum zinc oxide (AZO). In the case where the first and second sub-pixel electrode 1210 and 2210, respectively, include a reflective electrode, the first and second sub-pixel electrode 1210 and 2210, respectively, may include a reflective layer including Ag, Mg, Al, Pt, Pd, Au, Ni, Nd, Ir, Cr, or a compound thereof, and a layer on the reflective layer, the layer including ITO, IZO, ZnO or In₂O₃. In an embodiment, the first and second sub-pixel electrodes 1210 and 2210, respectively, may have a structure in which an ITO layer, an Ag layer, and an ITO layer are sequentially stacked. However, the embodiment is not limited thereto and the first and second sub-pixel electrode 1210 and 2210, respectively, may include various materials, and the structure thereof may be a single layer or a multi-layer and be variously modified. The first and second sub-pixel electrode 1210 and 2210, respectively, may be electrically connected to the connection metals CM through contact holes of the second organic insulating layer 109.

In an embodiment, an insulating layer 111 may cover an edge region (or an edge) of the first and second sub-pixel electrodes 1210 and 2210, respectively. The insulating layer 111 may include an opening exposing a portion of the first and second sub-pixel electrodes 1210 and 2210, respectively. As an example, the insulating layer 111 may include first and second openings 111OP1 and 111OP2, respectively, exposing the first and second sub-pixel electrodes 1210 and 2210, respectively. The first and second openings 111OP1 and 111OP2, respectively, of the insulating layer 111 may correspond to regions from which light of the first and second light-emitting diodes LED1 and LED2, respectively, is emitted, that is, emission areas. The emission area may correspond to the sub-pixel P (see FIG. 1B) described above with reference to FIG. 1B. The insulating layer 111 may include, for example, an inorganic insulating material such as silicon nitride, silicon oxynitride, and/or silicon oxide, and include a single layer or a multi-layer including the above inorganic insulating materials.

In an embodiment, a protective layer 113 may be disposed between the second organic insulating layer 109 and the insulating layer 111. The protective layer 113 may include openings overlapping the first and second sub-pixel electrodes 1210 and 2210, respectively. The width of the protective layer 113 may be greater than the width of the first and second openings 111OP1 and 111OP2, respectively, of the insulating layer 111. In other words, the lateral surface (or the edge) of the protective layer 113 defining the opening of the protective layer 113 may be located under the insulating layer 111. The protective layer 113 may include a conductive oxide such as ITO, IZO, IGZO, ITZO, ZnO, AZO, GZO, ZTO, GTO, and FTO.

In an embodiment, first and second intermediate layers 1220 and 2220, respectively, may be respectively disposed on the first and second sub-pixel electrodes 1210 and 2210. The first and second intermediate layers 1220 and 2220, respectively, may include an organic emission layer (EML) including a low-molecular weight material or a polymer material. In the case where the organic emission layer includes a low molecular weight material, the first and second intermediate layers may have a structure in which a hole injection layer (HIL), a hole transport layer (HTL), an organic emission layer (EML), an electron transport layer (ETL), and/or an electron injection layer (EIL), etc. are stacked in a single or composite configuration.

In an embodiment, first and second opposite electrodes 1230 and 2230, respectively, are respectively disposed on the first and second intermediate layers 1220 and 2220. The first and second opposite electrodes 1230 and 2230, respectively, arranged in the sub-pixel areas PA may respectively overlap the first and second intermediate layers 1220 and 2220, respectively, through first and second openings 300OP1 and 300OP2, respectively, of the conductive bank layer 300. The first and second opposite electrodes 1230 and 2230, respectively, may be electrically connected to a conductive bank layer 300 by being in contact with the lateral surface of the conductive bank layer 300 (e.g., the lateral surface of a first conductive layer 310) facing the first and second openings 300OP1 and 300OP2, respectively.

In an embodiment, the first and second opposite electrodes 1230 and 2230, respectively, may include a (semi) transparent electrode. In the case where the first and second opposite electrodes 1230 and 2230, respectively, include the (semi) transparent electrode, the first and second opposite electrodes 1230 and 2230, respectively, may include at least one of Ag, Al, Mg, Li, Ca, Cu, LiF/Ca, LiF/Al, MgAg, and CaAg and may be formed in the form of a thin-film having a thickness of several to tens of nm. The construction and material of the first and second opposite electrodes 1230 and 2230, respectively, are not limited thereto and various modifications may be made.

In an embodiment, the conductive bank layer 300 may be disposed on the insulating layer 111. The conductive bank layer 300 may have a stack structure of the first conductive layer 310 and a second conductive layer 320 on the first conductive layer 310. The first conductive layer 310 and the second conductive layer 320 may include different metals. As an example, the first conductive layer 310 and the second conductive layer 320 may include metals with different etching selectivities. In an embodiment, the first conductive layer 310 may include a layer including aluminum (Al), and the second conductive layer 320 may include a layer including titanium (Ti). The thickness of the first conductive layer 310 may be greater than the thickness of the second conductive layer 320. In an embodiment, the thickness of the first conductive layer 310 may be greater than about 5 times the thickness of the second conductive layer 320. In another embodiment, the thickness of the first conductive layer 310 may be greater than about 6 times, greater than about 7 times, or greater than about 8 times the thickness of the second conductive layer 320. In an embodiment, the thickness of the first conductive layer 310 may be about 4000 Å to about 8000 Å, and the thickness of the second conductive layer 320 may be about 500 Å to about 800 Å.

In an embodiment, the conductive bank layer 300 may include the first and second openings 300OP1 and 300OP2, respectively, passing through the bottom surface from the upper surface of the conductive bank layer 300. The first and second openings 300OP1 and 300OP2, respectively, of the conductive bank layer 300 may respectively overlap the first and second sub-pixel electrodes 1210 and 2210, respectively. As an example, the conductive bank layer 300 may include the first opening 300OP1 overlapping the first sub-pixel electrode 1210 and passing through the bottom surface from the upper surface of the conductive bank layer 300. The conductive bank layer 300 may include the second opening 300OP2 overlapping the second sub-pixel electrode 2210 and passing through the bottom surface from the upper surface of the conductive bank layer 300.

In an embodiment, the conductive bank layer 300 may include a hole 300H arranged between the first opening 300OP1 and the second opening 300OP2, or arranged in the non-sub-pixel area NPA between adjacent sub-pixel areas PA. A depth d1 of the hole 300H may be less than a thickness t1 of the conductive bank layer 300. The hole 300H may be a blind hole that does not pass through the first conductive layer 310. As an example, the hole 300H may be formed to pass through the bottom surface from the upper surface of the second conductive layer 320, and pass through the upper surface of the first conductive layer 310 to have a preset depth.

In an embodiment, an organic layer 400 may be disposed on the conductive bank layer 300. The organic layer 400 may include an opening 400OP1 and an opening 400OP2, wherein the opening 400OP1 overlaps the first sub-pixel electrode 1210 and the first opening 300OP1 of the conductive bank layer 300, and the opening 400OP2 overlaps the second sub-pixel electrode 2210 and the second opening 300OP2 of the conductive bank layer 300. The width of the opening 400OP1 formed in the organic layer 400 to overlap the first opening 300OP1 of the conductive bank layer 300 may be greater than the width of the first opening 300OP1 of the conductive bank layer 300. The width of the opening 400OP2 formed in the organic layer 400 to overlap the second opening 300OP2 of the conductive bank layer 300 may be greater than the width of the second opening 300OP2 of the conductive bank layer 300.

In an embodiment, the organic layer 400 may include an organic material portion 1400 disposed on the conductive bank layer 300 in the non-sub-pixel area NPA. The organic material portion 1400 may be in contact with the upper surface of the conductive bank layer 300. At least a portion of the organic material layer 1400 may be disposed in the hole 300H. Although it is shown in FIG. 2 that the thicknesses of the organic layer 400 and the organic material portion 1400 are the same as the depth d1 of the hole 300H, this is an example and the thickness of the organic material portion 1400 may be greater than or less than the depth d1 of the hole 300H. In other words, the organic material portion 1400 may protrude from the upper surface of the second conductive layer 320 or be recessed from the upper surface of the second conductive layer 320. The organic layer 400 may include an organic insulating material. As an example, the organic layer 400 may include colored pigment or dye. As an example, the organic layer 400 may include black pigment.

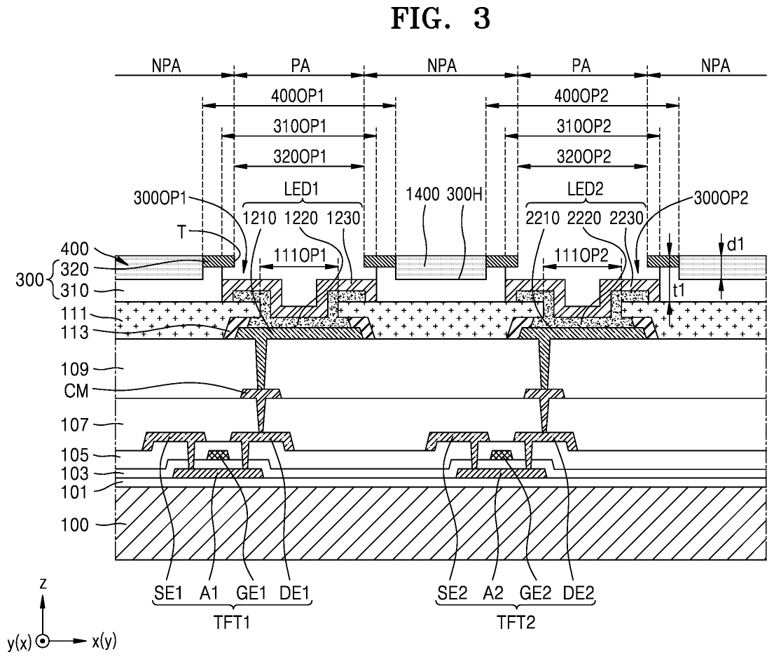

FIG. 3 is a schematic cross-sectional view of the display apparatus 1, according to another embodiment.

In an embodiment and referring to FIG. 3, with the exception of the characteristics of the structure of a tip T, the other characteristics are the same as those described in FIG. 2. Accordingly, the same reference numerals among elements of FIG. 3 are replaced with those previously described with reference to FIG. 2, and differences are mainly described below.

In an embodiment and referring to FIG. 3, the first and second openings 300OP1 and 300OP2, respectively, of the conductive bank layer 300 may form an undercut structure. The width of openings 310OP1 and 310OP2 of the first conductive layer 310 respectively corresponding to the first and second openings 300OP1 and 300OP2, respectively, of the conductive bank layer 300 may be greater than the width of openings 320OP1 and 320OP2 of the second conductive layer 320.

In an embodiment, a portion of the second conductive layer 320 may protrude to the first and second openings 300OP1 and 300OP2, respectively, of the conductive bank layer 300 from a point at which the lateral surface of the first conductive layer 310 facing each of the first and second openings 300OP1 and 300OP2, respectively, of the conductive bank layer 300 meets the bottom surface of the second conductive layer 320, and may form an undercut structure. A portion of the second conductive layer 320 protruding to the first and second openings 300OP1 and 300OP2, respectively, of the conductive bank layer 300 may correspond to the tip T. The length of the tip T, for example, a length between the lateral surface (or the edge) of the tip T and a point at which the lateral surface of the first conductive layer 310 facing each of the first and second openings 300OP1 and 300OP2, respectively, of the conductive bank layer 300 meets the bottom surface of the second conductive layer 320 may be about 2 μm or less. In an embodiment, the length of the tip T may be about 0.3 μm to about 1 μm, or about 0.3 μm to about 0.7 μm.

Although it is shown in FIG. 3 that the openings 310OP1 and 310OP2 of the first conductive layer 310 have a shape having a constant width in a z direction, the embodiment is not limited thereto. In an embodiment, the openings 310OP1 and 310OP2 of the first conductive layer 310 may have a shape having a reducing width toward the lower portion. As an example, the width of the upper portion of the opening 310OP1 and 310OP2 of the first conductive layer 310 may be greater than the width of the lower portion. In other words, the lateral surface of the first conductive layer 310 facing the first and second openings 300OP1 and 300OP2, respectively, of the conductive bank layer 300 may include a forward tapered inclined surface.

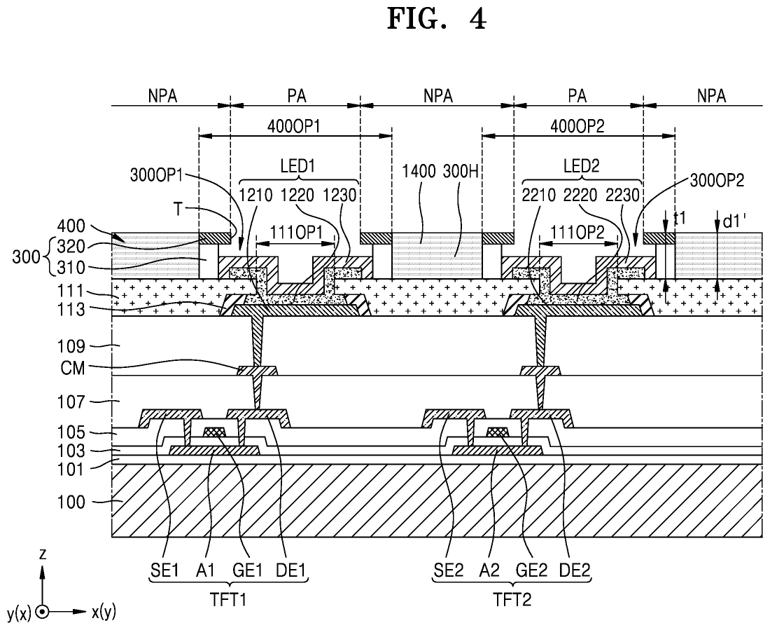

FIG. 4 is a schematic cross-sectional view of the display apparatus 1, according to another embodiment.

In an embodiment and referring to FIG. 4, with the exception of the characteristics of the hole 300H and the organic layer 400, the other characteristics are the same as those described in FIGS. 2 and 3. Accordingly, the same reference numerals among elements of FIG. 4 are replaced with those previously described with reference to FIGS. 2 and 3, and differences are mainly described below.

In an embodiment and referring to FIG. 4, the conductive bank layer 300 may include the hole 300H arranged in the non-sub-pixel area NPA. The hole 300H may be formed to pass through the conductive bank layer 300. In other words, a depth d1′ of the hole 300H may be substantially equal to a thickness t1 of the conductive bank layer 300. The hole 300H may have a through-hole shape passing through the conductive bank layer 300.

In an embodiment, the organic material portion 1400 of the organic layer 400 may be disposed in the hole 300H of the conductive bank layer 300 in the non-sub-pixel area NPA. At least a portion of the organic material portion 1400 may fill the hole 300H of the conductive bank layer 300. In this case, because the hole 300H passes through the second conductive layer 320 and the first conductive layer 310, the organic material portion 1400 may be disposed to pass through the second conductive layer 320 and the first conductive layer 310. In other words, the organic material portion 1400 may be in direct contact with the upper surface of the insulating layer 111 through the hole 300H.

In an embodiment, although it is shown in FIG. 4 that the thicknesses of the organic layer 400 and the organic material portion 1400 are the same as the depth d1′ of the hole 300H, this is an example and the thickness of the organic layer 400 and/or the organic material portion 1400 may be greater than the depth d1′ of the hole 300H. As an example, the upper surface of the organic material portion 1400 may not have the same level as the upper surface of the second conductive layer 320.

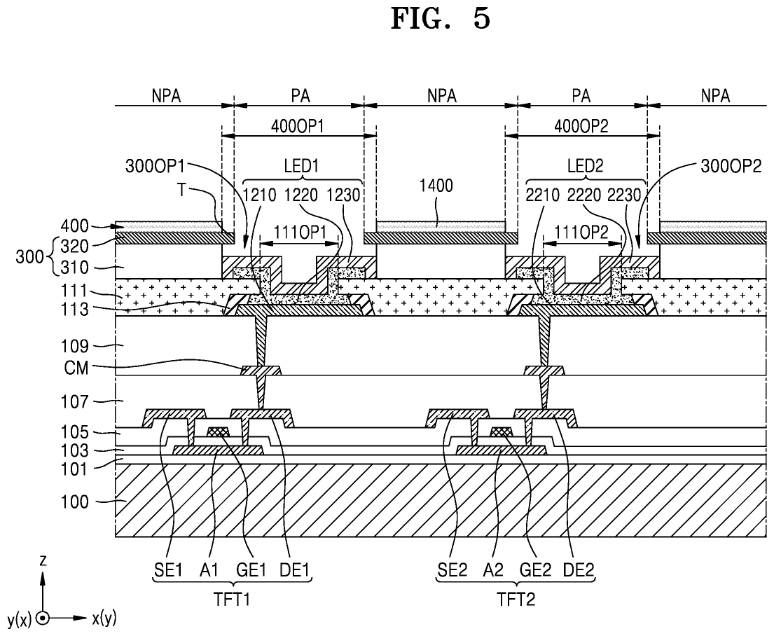

FIG. 5 is a schematic cross-sectional view of the display apparatus 1, according to another embodiment.

In an embodiment and referring to FIG. 5, with the exception of the characteristics of the conductive bank layer 300 and the organic layer 400, the other characteristics are the same as those described in FIGS. 2 and 3. Accordingly, the same reference numerals among elements of FIG. 5 are replaced with those previously described with reference to FIGS. 2 and 3, and differences are mainly described below.

In an embodiment, the conductive bank layer 300 may not have the hole 300H shown in FIGS. 2 to 4 in the non-sub-pixel area NPA.

In an embodiment, the organic layer 400 may be formed on the conductive bank layer 300. In this case, the bottom surface of the organic layer 400 may be in direct contact with the upper surface of the second conductive layer 320. As an example, the organic material portion 1400 of the organic layer 400 may be disposed on the upper surface of the second conductive layer 320 in the non-sub-pixel area NPA.

In an embodiment, although it is shown in FIG. 5 that the thickness of the organic layer 400 is substantially the same as the thickness of the second conductive layer 320, the embodiment is not limited thereto and the thickness of the organic layer 400 is greater than or less than the thickness of the second conductive layer 320. Although it is shown in FIG. 5 that the organic material portion 1400 of the organic layer 400 overlaps a portion of the upper surface of the second conductive layer 320 in the non-sub-pixel area NPA, the embodiment is not limited thereto. In another embodiment, the organic material portion 1400 of the organic layer 400 may overlap the upper surface of the second conductive layer 320 entirely. As an example, the organic material portion 1400 of the organic layer 400 may overlap the tip T.

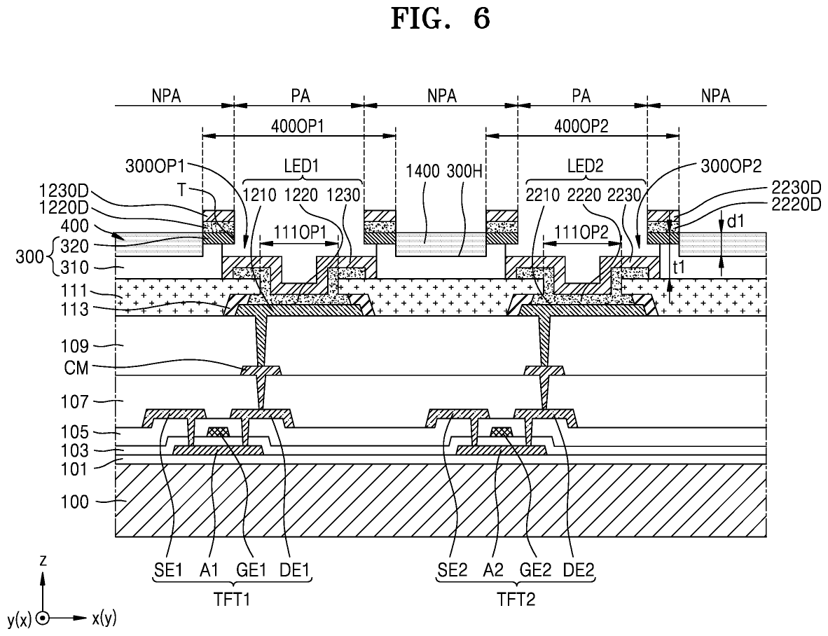

FIG. 6 is a schematic cross-sectional view of the display apparatus 1, according to another embodiment.

In an embodiment and referring to FIG. 6, with the exception of the characteristics of first and second dummy intermediate layers 1220D and 2220D, respectively, and first and second dummy opposite electrodes 1230D and 2230D, respectively, the other characteristics are the same as those described with reference to FIGS. 2 and 3. Accordingly, the same reference numerals among elements of FIG. 6 are replaced with those previously described with reference to FIGS. 2 and 3, and differences are mainly described below.

In an embodiment, a stack structure of the first dummy intermediate layer 1220D and the first dummy opposite electrode 1230D may be disposed on the tip T of the conductive bank layer 300 arranged around the first light-emitting diode LED1. A stack structure of the second dummy intermediate layer 2220D and the second dummy opposite electrode 2230D may be disposed on the tip T of the conductive bank layer 300 arranged around the second light-emitting diode LED2.

In an embodiment, the first dummy intermediate layer 1220D may include the same material as a material of the first intermediate layer 1220. The second dummy intermediate layer 2220D may include the same material as a material of the second intermediate layer 2220. Because the first intermediate layer 1220 and the second intermediate layer 2220 respectively include different materials to emit light of different colors, the first dummy intermediate layer 1220D and the second dummy intermediate layer 2220D may respectively include different materials.

In an embodiment, the first dummy opposite electrode 1230D may include the same material as a material of the first opposite electrode 1230. The second dummy opposite electrode 2230D may include the same material as a material of the second opposite electrode 2230.

In an embodiment shown in FIGS. 2 to 6, although it is shown that the conductive bank layer 300 includes the first conductive layer 310 and the second conductive layer 320 on the first conductive layer 310, the embodiment is not limited thereto. In another embodiment, the conductive bank layer 300 may include the first conductive layer 310, the second conductive layer 320 on the first conductive layer 310, and a third conductive layer under the first conductive layer 310. The third conductive layer may include a material which is the same as or different from a material of the first conductive layer 310.

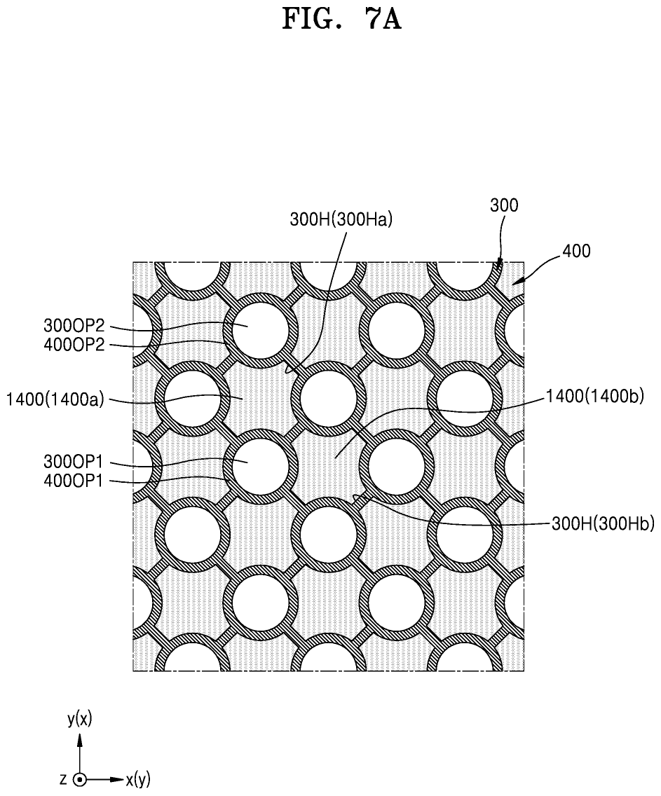

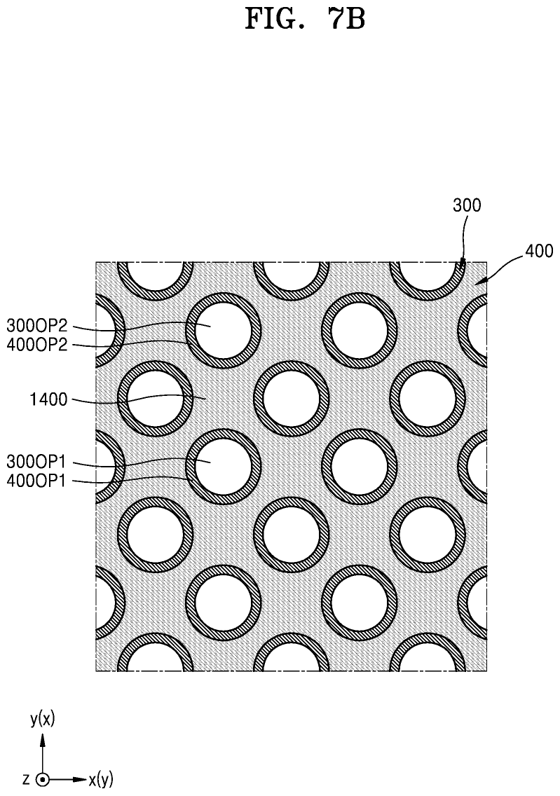

FIGS. 7A and 7B are schematic plan views of the display apparatus, according to an embodiment.

In an embodiment, FIG. 7A may correspond to a planar structure of the embodiment shown in FIG. 4.

In an embodiment and referring to FIG. 7A, the conductive bank layer 300 may include the first opening 300OP1 overlapping the sub-pixel area PA (see FIG. 4) as described above with reference to FIG. 4. The conductive bank layer 300 may include the second opening 300OP2 overlapping the sub-pixel area PA (see FIG. 4) and adjacent to the first opening 300OP1. The first opening 300OP1 of the conductive bank layer 300 may overlap the first sub-pixel electrode 1210 (see FIG. 4). The second opening 300OP2 of the conductive bank layer 300 may overlap the second sub-pixel electrode 2210 (see FIG. 4).

In an embodiment, a first hole 300Ha may be formed in the non-sub-pixel area between the first opening 300OP1 and the second opening 300OP2. A second hole 300Hb may be formed adjacent to the first hole 300Ha in the non-sub-pixel area.

In an embodiment, the first hole 300Ha may be spatially separated from the second hole 300Hb. A portion of the conductive bank layer 300 may be arranged between the first hole 300Ha and the second hole 300Hb, and thus, the first hole 300Ha may be spatially separated from the second hole 300Hb.

In an embodiment, the organic layer 400 may include the opening 400OP1 overlapping the first opening 300OP1 of the conductive bank layer 300 and the opening 400OP2 overlapping the second opening 300OP2 of the conductive bank layer 300.

In an embodiment, the organic layer 400 may include a first organic material portion 1400a and a second organic material portion 1400b, wherein at least a portion of the first organic material portion 1400a is present in the first hole 300Ha, and at least a portion of the second organic material portion 1400b is present in the second hole 300Hb. The first organic material portion 1400a may be separated and apart from the second organic material portion 1400b.

In an embodiment, although it is shown in FIG. 7A that the hole 300H is a through hole, the embodiment is not limited thereto. In another embodiment, as described with reference to FIG. 3, each of the first hole 300Ha and the second hole 300Hb may be a blind hole.

FIG. 7b is a plan view of the embodiment shown in FIG. 5.

In an embodiment and as described with reference to FIG. 5, the conductive bank layer 300 may not include the hole 300H (see FIG. 5), and the organic material portion 1400 may be disposed such that the bottom surface of the organic material portion 1400 is in direct contact with the upper surface of the second conductive layer 320 (see FIG. 5). The organic layer 400 may include the opening 400OP1 overlapping the first opening 300OP1 of the conductive bank layer 300, and the opening 400OP2 overlapping the second opening 300OP2 of the conductive bank layer 300. The organic material portion 1400 may be disposed on the upper surface of the second conductive layer 320 (see FIG. 5) without being separated. The lower surface of the organic material layer 1400 may be in direct contact with the upper surface of the second conductive layer 320 (see FIG. 5).

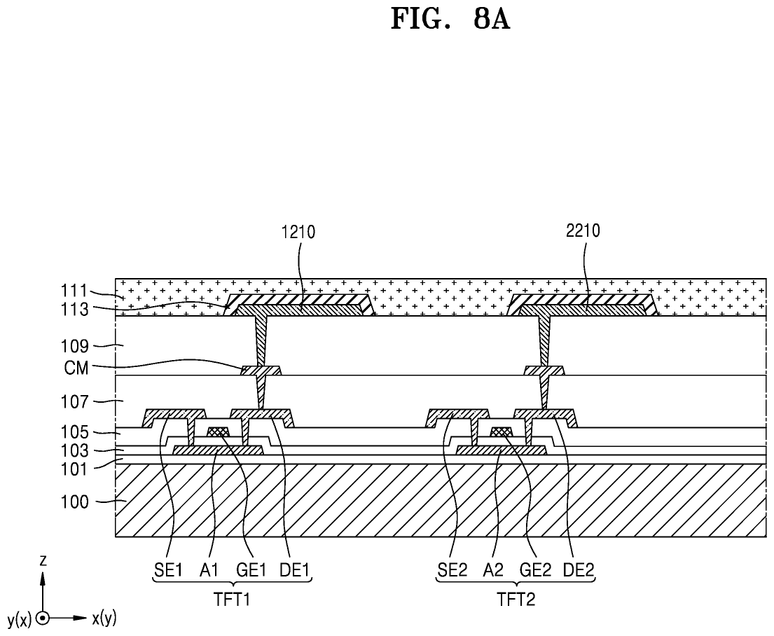

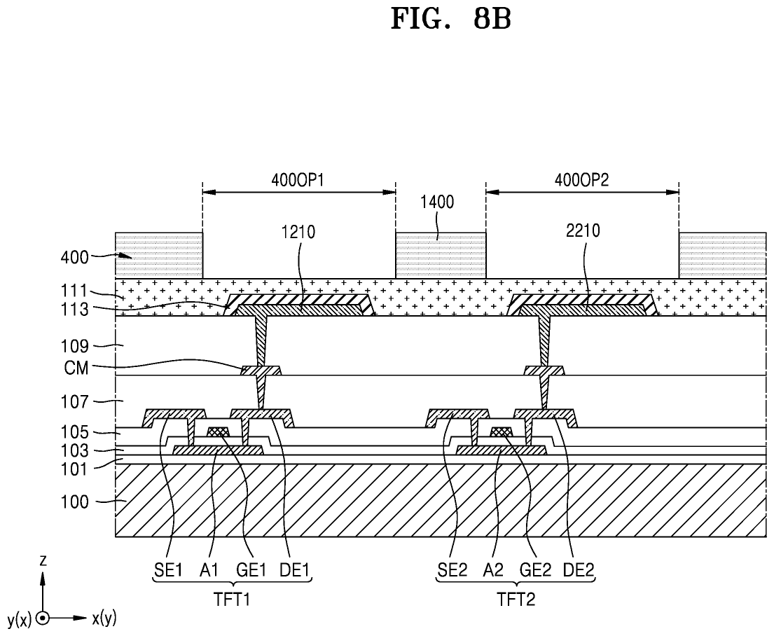

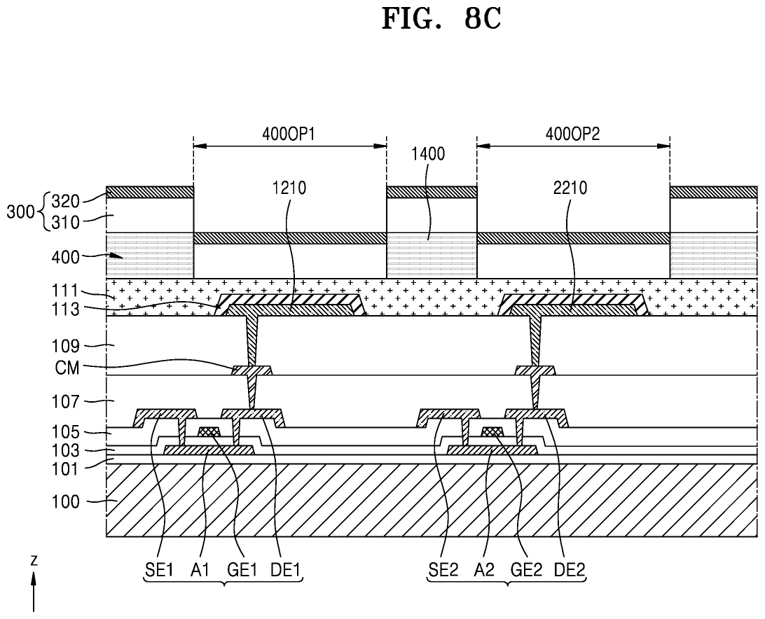

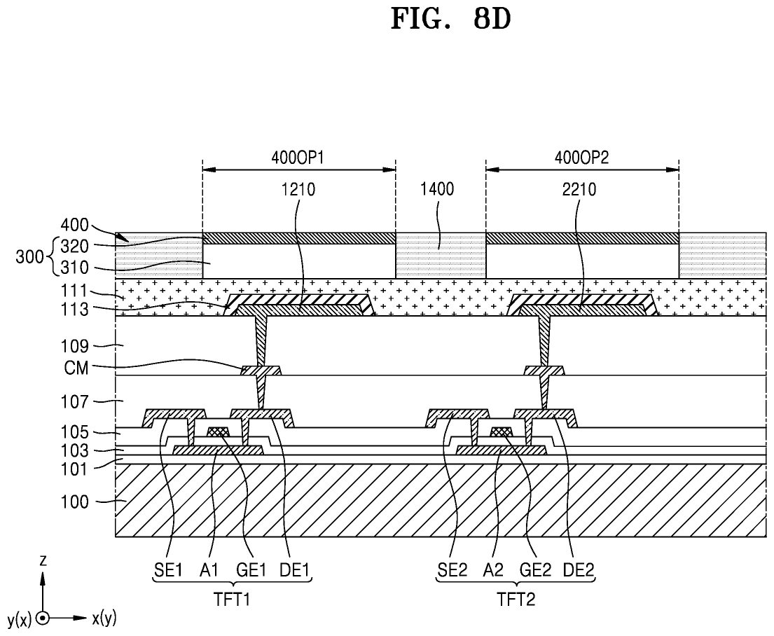

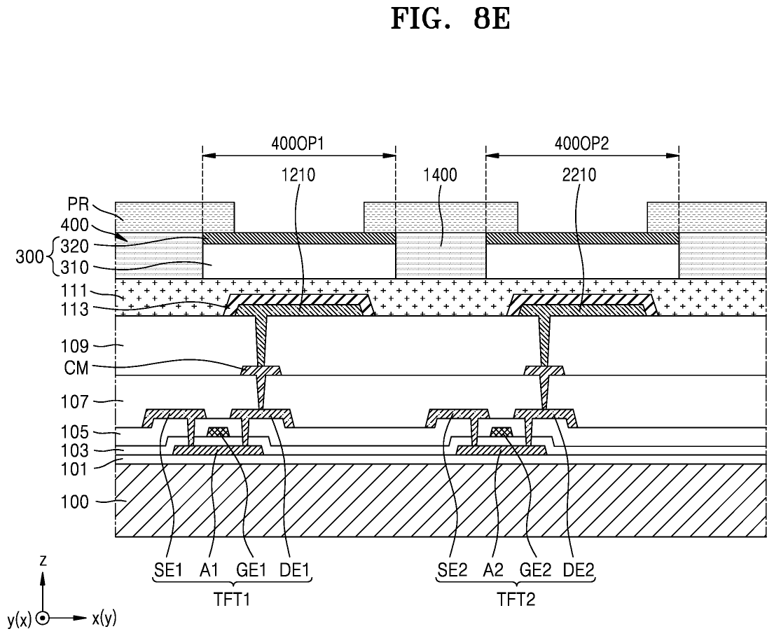

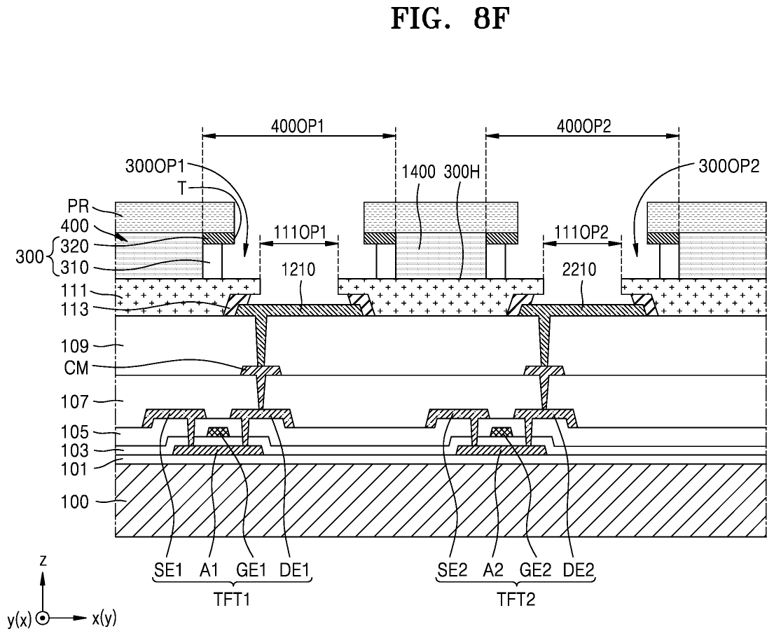

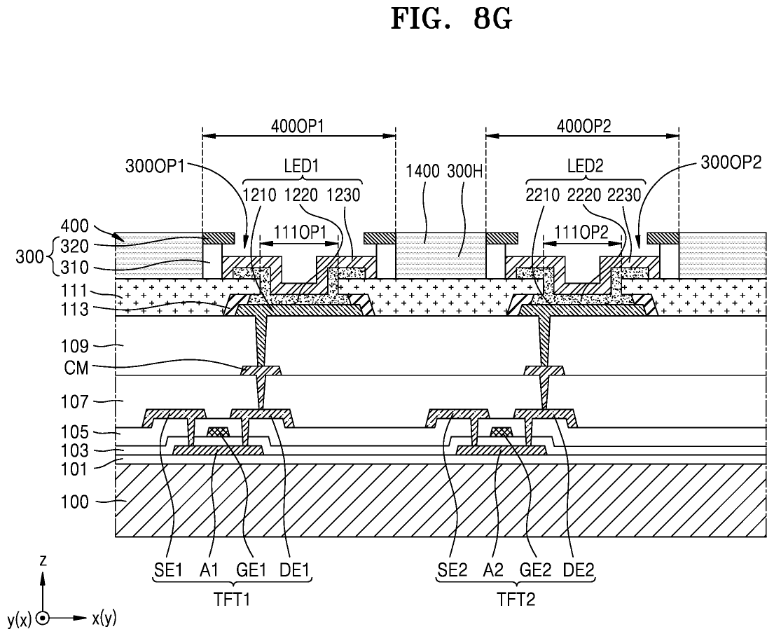

FIGS. 8A to 8G are schematic cross-sectional views showing states corresponding to a process of manufacturing the display apparatus, according to an embodiment.

In an embodiment and referring to FIG. 8A, the first sub-pixel electrode 1210 and the second sub-pixel electrode 2210 may be formed apart from each other over the substrate 100. The first sub-pixel electrode 1210 and the second sub-pixel electrode 2210 may be formed simultaneously during the same process and may include the same material.

In an embodiment, before the first sub-pixel electrode 1210 and the second sub-pixel electrode 2210 are formed, the first thin-film transistor TFT1, the second thin-film transistor TFT2, and the insulating layers may be formed. The buffer layer 101, the gate insulating layer 103, the interlayer insulating layer 105, the first thin-film transistor TFT1, the second thin-film transistor TFT2, the first organic insulating layer 107, the second organic insulating layer 109, and the connection metal CM may be formed between the substrate 100 and the first sub-pixel electrode 1210 and the second sub-pixel electrode 2210. It is shown that the first thin-film transistor TFT1 and the second thin-film transistor TFT2 of FIG. 8A have the same structure as a structure of thin-film transistor TFT1 and the second thin-film transistor TFT2 (see FIG. 2) described above with reference to FIG. 2.

In an embodiment and referring to FIG. 8B, the organic layer 400 may be formed on the insulating layer 111. The organic layer 400 may include the first opening 400OP1 and the second opening 400OP2, wherein the first opening 400OP1 overlaps the first sub-pixel electrode 1210, and the second opening 400OP2 overlaps the second sub-pixel electrode 2210. The organic layer 400 may include the organic material portion 1400 arranged between the first opening 400OP1 and the second opening 400OP2.

In an embodiment and referring to FIG. 8C, the conductive bank layer 300 may be formed on the organic layer 400 and the insulating layer 111. A portion of the conductive bank layer 300 may overlap the first opening 400OP1 and the second opening 400OP2 of the organic layer 400, and the lower surface of the conductive bank layer 300 may be in direct contact with the upper surface of the insulating layer 111. The lower surface of the rest of the conductive bank layer 300 may be in direct contact with the upper surface of the organic layer 400. The conductive bank layer 300 may include the first conductive layer 310 and the second conductive layer 320 on the first conductive layer 310. Although it is shown in FIG. 8C that the thickness of a portion of the conductive bank layer 300 that overlaps the first and second openings 400OP1 and 400OP2, respectively, of the organic layer 400 is equal to the thickness of the organic layer 400, the thickness of the conductive bank layer 300 may be greater than or less than the thickness of the organic layer 400.

In an embodiment and referring to FIG. 8D, a portion of the conductive bank layer 300 that overlaps the organic layer 400 may be removed. As an example, a portion of the conductive bank layer 300 that overlaps the organic material portion 1400 may be etched. The etching of the conductive bank layer 300 may be performed through dry etching. The upper surface of the organic material portion 1400 may be exposed through the etching of the conductive bank layer 300.

In an embodiment and referring to FIG. 8E, a photoresist PR may be formed on the conductive bank layer 300. As shown in FIG. 8E, in an embodiment, the photoresist PR may include openings respectively overlapping the first sub-pixel electrode 1210 and the second sub-pixel electrode 2210. In other words, a portion of the upper surface of the conductive bank layer 300 may be exposed through each opening of the photoresist PR.

In an embodiment and referring to FIG. 8F, a portion of the conductive bank layer 300, for example, a portion of the second conductive layer 320 and a portion of the first conductive layer 310 may be removed using the photoresist PR as a mask. A portion of the second conductive layer 320 and a portion of the first conductive layer 310 may be removed by dry etching. During the etching process, the insulating layer 111 and the protective layer 113 may be configured to protect the first and second sub-pixel electrodes 1210 and 2210, respectively, thereunder.

In an embodiment, by the etching process, the first and second openings 300OP1 and 300OP2, respectively, may be formed in the conductive bank layer 300 wherein the first and second openings 300OP1 and 300OP2, respectively, overlap a portion of the first and second sub-pixel electrodes 1210 and 2210, respectively, and the protective layer 113 and pass through the conductive bank layer 300. As an example, the first opening 300OP1 may be formed in the conductive bank layer 300, wherein the first opening 300OP1 overlaps a portion of the first sub-pixel electrode 1210 and the protective layer 113 and passes through the conductive bank layer 300. The second opening 300OP2 may be formed in the conductive bank layer 300, wherein the second opening 300OP2 overlaps a portion of the second sub-pixel electrode 2210 and the protective layer 113 and passes through the conductive bank layer 300.

In an embodiment, a portion of the first conductive layer 310 may be further etched, and the second conductive layer 320 may have the tip T. In an embodiment, it is shown in FIG. 8F that the tip T has the same structure as a structure of the tip T described with reference to FIG. 3.

In an embodiment, a portion of the insulating layer 111 may be removed. In an embodiment, the width of the first and second openings 111OP1 and 111OP2 of the insulating layer 111 may be less than the width of the first and second openings 300OP1 and 300OP2 of the conductive bank layer 300. As an example, a point at which the lateral surface of the first conductive layer 310 meets the bottom surface may meet the upper surface of the insulating layer 111.

In an embodiment, a portion of the protective layer 113 may be removed. The first and second sub-pixel electrodes 1210 and 2210 may be exposed through the openings of the protective layer 113. Because a portion of the protective layer 113 is removed, the width of the openings of the protective layer 113 may be greater than the width of the first and second openings 111OP1 and 111OP2 of the insulating layer 111. In other words, the lateral surface (or the edge) of the protective layer 113 defining the opening of the protective layer 113 may be located under the insulating layer 111. As an example, the width of the opening of the protective layer 113 formed by removing a portion of the protective layer 113 overlapping the first sub-pixel electrode 1210 may be greater than the width of the first opening 111OP1 of the insulating layer 111 overlapping the first sub-pixel electrode 1210. The width of the opening of the protective layer 113 formed by removing a portion of the protective layer 113 overlapping the second sub-pixel electrode 2210 may be greater than the width of the second opening 111OP2 of the insulating layer 111 overlapping the second sub-pixel electrode 2210.

Then, the photoresist PR is removed.

In an embodiment and referring to FIG. 8G, the first and second intermediate layers 1220 and 2220, respectively, and the first and second opposite electrodes 1230 and 2230, respectively, may be formed to overlap the first and second sub-pixel electrodes 1210 and 2210, respectively, on the structure formed by removing the photoresist PR from the structure of FIG. 8F. Stack structures of the first and second sub-pixel electrodes 1210 and 2210, respectively, the first and second intermediate layers 1220 and 2220, respectively, and the first and second opposite electrodes 1230 and 2230, respectively, may respectively correspond to the first and second light-emitting diodes LED1 and LED2. As an example, the stack structure of the first sub-pixel electrode 1210, the first intermediate layer 1220, and the first opposite electrode 1230 may correspond to the first light-emitting diode LED1. The stack structure of the second sub-pixel electrode 2210, the second intermediate layer 2220, and the second opposite electrode 2230 may correspond to the second light-emitting diode LED2.

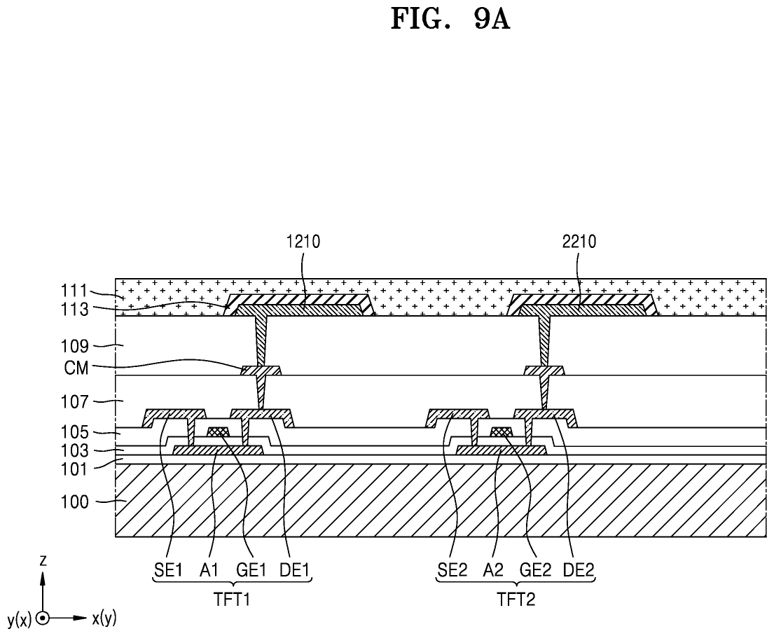

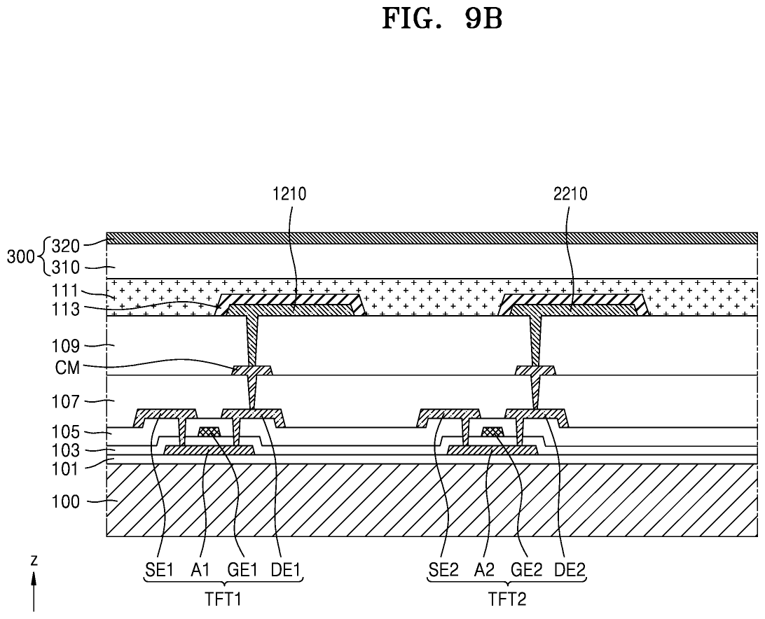

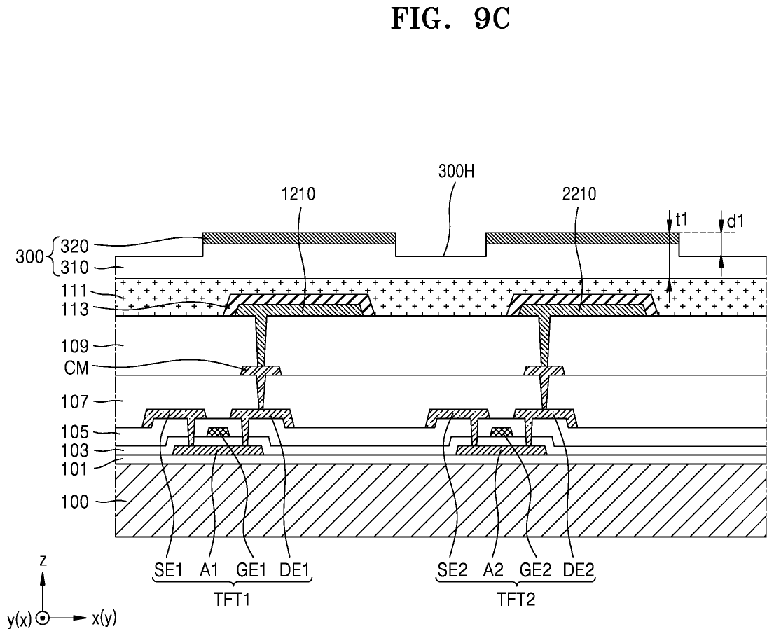

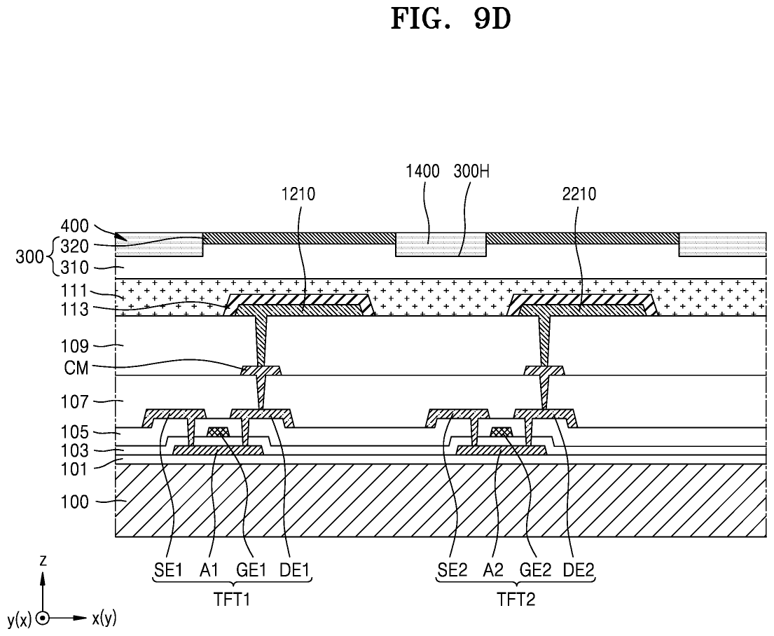

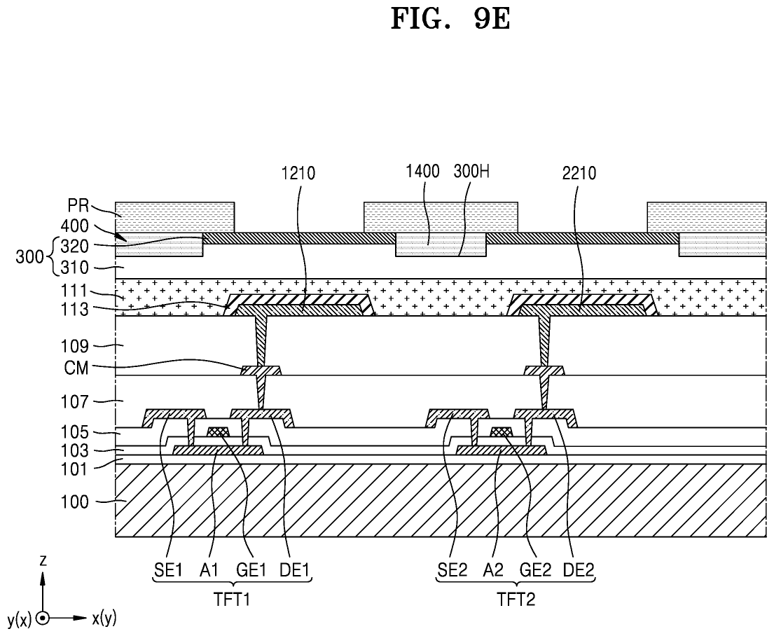

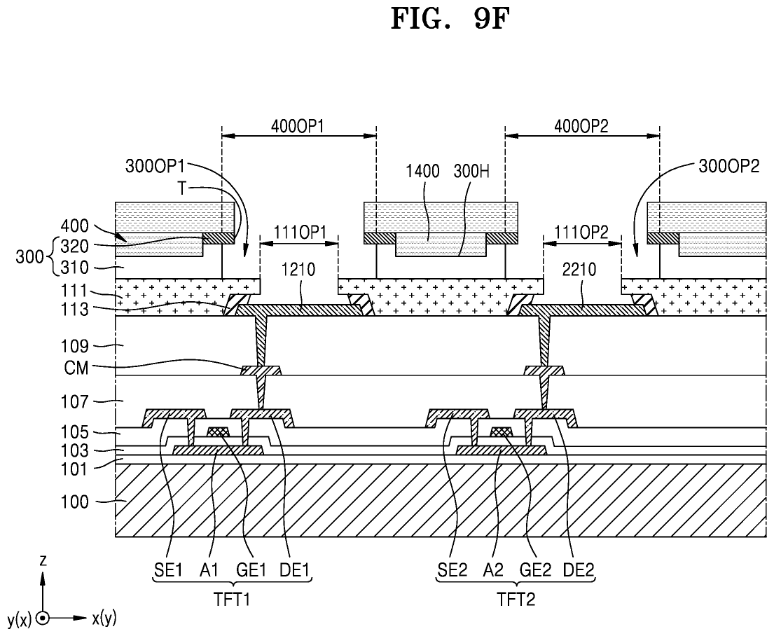

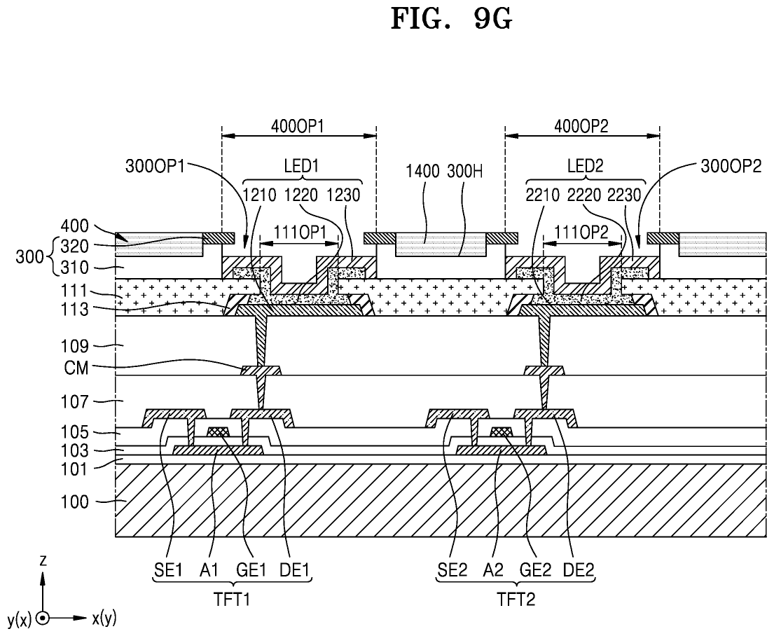

FIGS. 9A to 9G are schematic cross-sectional views showing states corresponding to an embodiment of a process of manufacturing the display apparatus according to the embodiment shown in FIG. 3.

The embodiment shown in FIG. 9A is identical to the embodiment shown in FIG. 8A, and thus, descriptions thereof are omitted.

Referring to FIG. 9B, the conductive bank layer 300 may be formed on the insulating layer 111. The conductive bank layer 300 may include the first conductive layer 310 and the second conductive layer 320 on the first conductive layer 310.

In an embodiment and referring to FIG. 9C, a portion of the conductive bank layer 300 that does not overlap the first and second sub-pixel electrodes 1210 and 2210 may be partially etched. The etching of the conductive bank layer 300 may be performed through dry etching. A portion of the second conductive layer 320 and a portion of the first conductive layer 310 may be removed through the etching of the conductive bank layer 300. The hole 300H may be formed in the conductive bank layer 300 through the etching of the conductive bank layer 300. The hole 300H may pass through the second conductive layer 320 and have a preset depth in the first conductive layer 310. In other words, the depth d1 of the hole 300H may be less than the thickness t1 of the conductive bank layer 300. The hole 300H may be a blind hole.

In an embodiment and referring to FIG. 9D, the organic layer 400 may be formed on the conductive bank layer 300. The organic layer 400 may include the organic material portion 1400, and at least a portion of the organic material portion 1400 may be disposed inside the hole 300H.

In an embodiment, although it is shown in FIG. 9D that the thicknesses of the organic layer 400 and the organic material portion 1400 are the same as the depth of the hole 300H, this is an example and the thickness of the organic material portion 1400 may be greater than or less than the depth of the hole 300H.

The elements shown in FIGS. 9E to 9G are the same as those described with reference to FIGS. 8E to 8G. Accordingly, the descriptions of the FIGS. 9E to 9G are replaced by the descriptions of the FIGS. 8E to 8G.

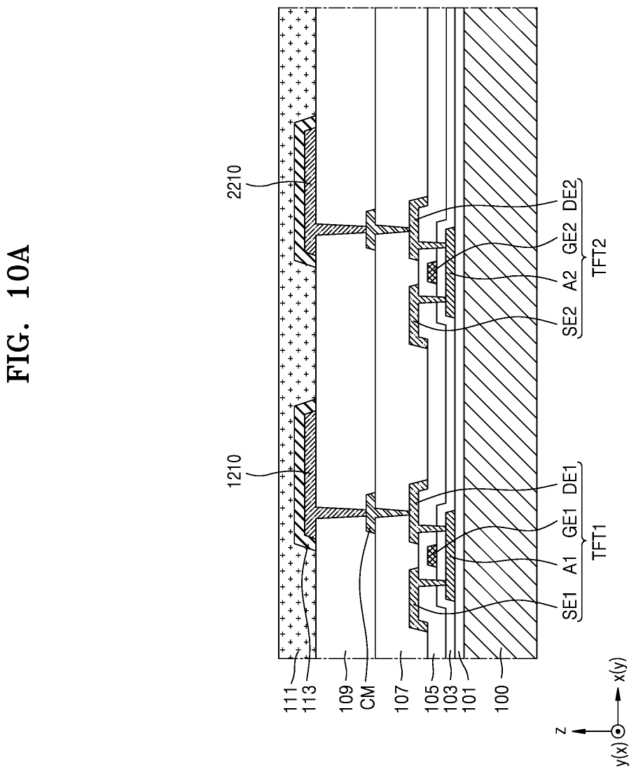

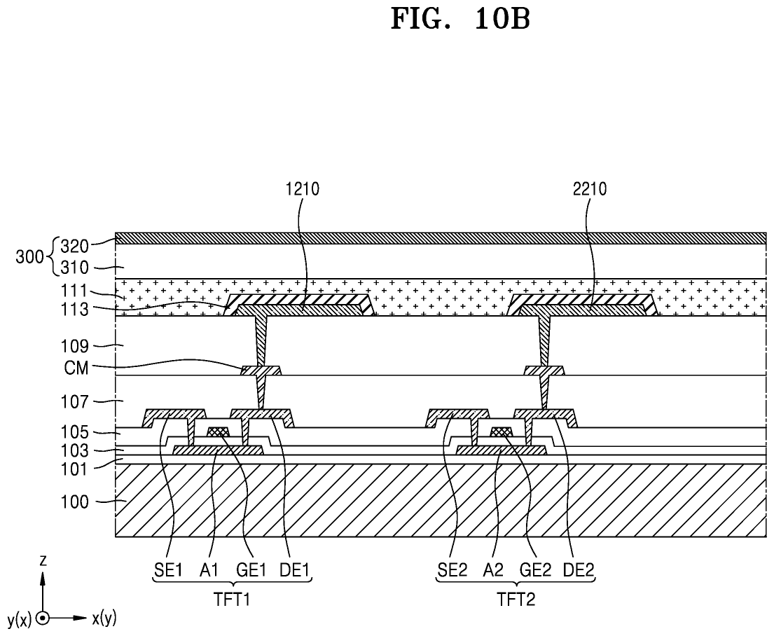

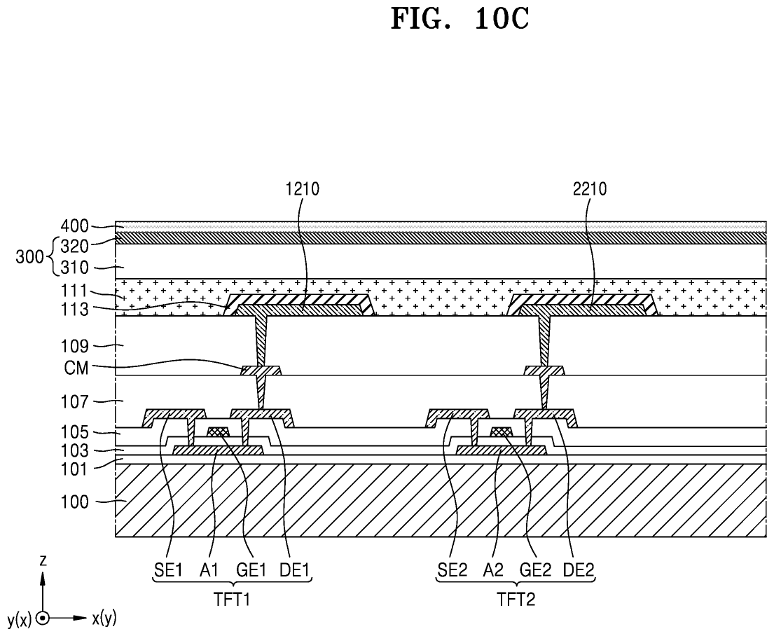

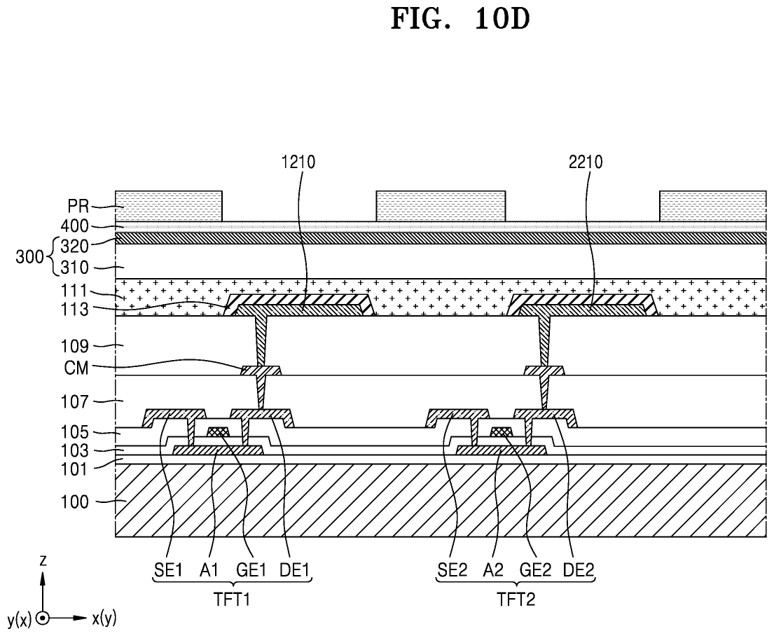

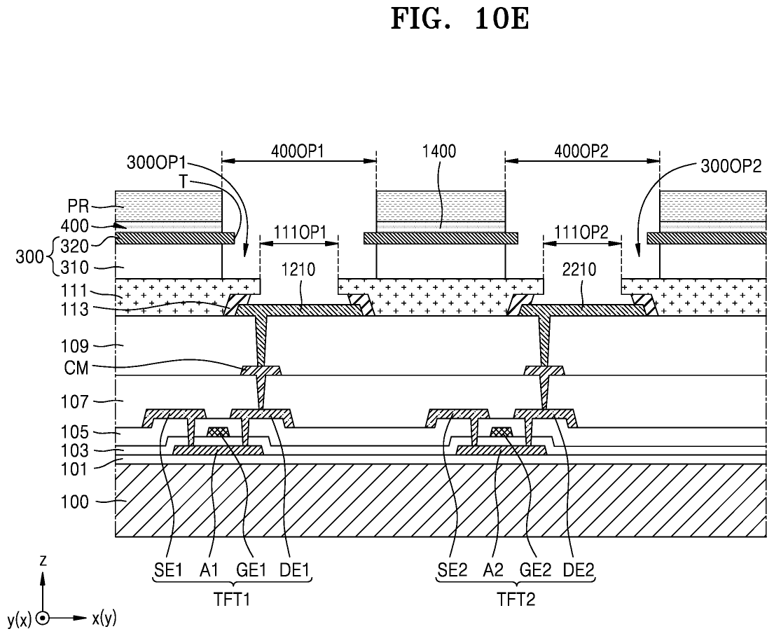

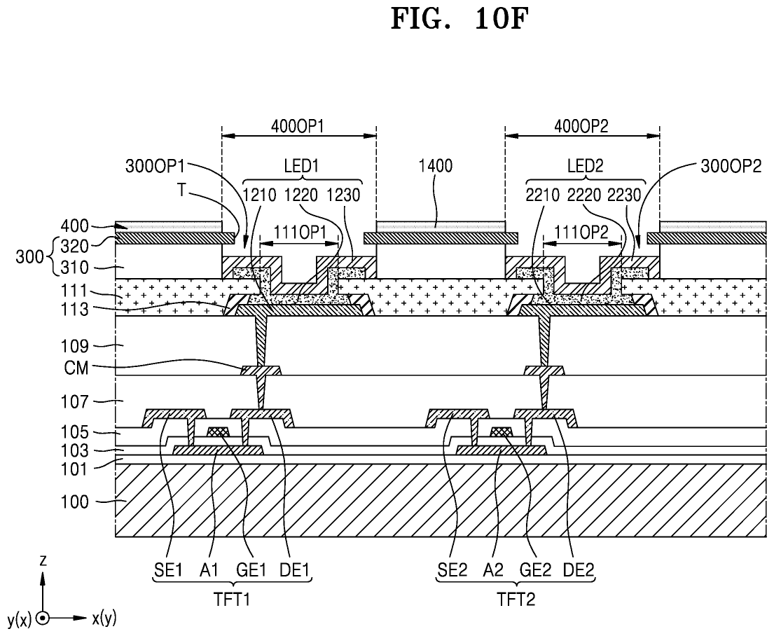

FIGS. 10A to 10G are schematic cross-sectional views showing states corresponding to an embodiment of a process of manufacturing the display apparatus according to the embodiment shown in FIG. 5.

The embodiment shown in FIG. 10A is identical to the embodiment shown in FIG. 8A, and thus, descriptions thereof are omitted.

The embodiment shown in FIG. 10B is identical to the embodiment shown in FIG. 9B, and thus, descriptions thereof are omitted.

In an embodiment and referring to FIG. 10C, the organic layer 400 may be formed on the conductive bank layer 300. As an example, the organic layer 400 may be formed such that the bottom surface of the organic layer 400 is in direct contact with the upper surface of the second conductive layer 320. Although it is shown in FIG. 10C that the thickness of the organic layer 400 is substantially identical to the thickness of the second conducive layer 320, the embodiment is not limited thereto. In another embodiment, the thickness of the organic layer 400 may be greater than the thickness of the second conductive layer 320 and less than the thickness of the first conductive layer 310.

In an embodiment and referring to FIG. 10D, a photoresist PR may be formed on the organic layer 400. Although not shown in FIG. 10D, in an embodiment, the photoresist PR may include openings respectively overlapping the first sub-pixel electrode 1210 and the second sub-pixel electrode 2210. In other words, a portion of the upper surface of the organic layer 400 may be exposed through each opening of the photoresist PR.

Referring to FIGS. 10E and 10F, with the exception of the characteristics of the organic layer 400, the other characteristics are the same as those described with reference to FIGS. 8F and 8G. Accordingly, same reference numerals among elements of FIGS. 10E and 10F are replaced with those previously described with reference to FIGS. 8F and 8G, and differences are mainly described below.

In an embodiment, a portion of the organic layer 400 may be etched. The etching of the organic layer 400 may be performed to pass through the organic layer 400. The organic layer 400 may include the first and second openings 400OP1 and 400OP2, respectively, overlapping the first and second sub-pixel electrodes 1210 and 2210, respectively. As an example, the organic layer 400 may include the first opening 400OP1 and/or the second opening 400OP2, wherein the first opening 400OP1 overlaps the first sub-pixel electrode 1210, and the second opening 400OP2 overlaps the second sub-pixel electrode 2210.

In an embodiment, the organic layer 400 may include the organic material portion 1400 overlapping a portion of the second conductive layer 320. In another embodiment, the organic material portion 1400 may overlap the upper surface of the second conductive layer 320 entirely. As an example, the organic material portion 1400 of the organic layer 400 may overlap the tip T.

According to an embodiment, because the organic layer is disposed on the conductive bank layer, reflectivity of external light may be reduced, and thus, the display apparatus configured to display high-quality images may be implemented. However, this effect is an example, and the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims. The embodiments of the present disclosure disclosed in the present disclosure and illustrated in the drawings are provided as particular examples for more easily explaining the technical contents according to the present disclosure and helping understand the embodiments of the present disclosure, but not intended to limit the scope of the embodiments of the present disclosure. Accordingly, the scope of the various embodiments of the present disclosure should be interpreted to include, in addition to the embodiments disclosed herein, all alterations or modifications derived from the technical ideas of the various embodiments of the present disclosure. Moreover, the embodiments or parts of the embodiments may be combined in whole or in part without departing from the scope of the invention.

What is claimed is:

1. A display apparatus comprising:
a first sub-pixel electrode arranged in a sub-pixel area;
a conductive bank layer disposed on the first sub-pixel electrode, including a first opening, a first conductive layer and a second conductive layer, wherein the first opening overlaps the first sub-pixel electrode;
a first intermediate layer disposed on the first sub-pixel electrode;
a first opposite electrode disposed on the first intermediate layer;
an insulating layer disposed between the conductive bank layer and an edge of the first sub-pixel electrode in a non-sub-pixel area which surrounds the sub-pixel area; and
an organic layer including an opening overlapping the first opening, and including a first organic material portion overlapping the insulating layer in the non-sub-pixel area.

2. The display apparatus of claim 1, wherein the conductive bank layer includes a first hole arranged in the non-sub-pixel area, wherein the first organic material portion is disposed inside the first hole.

3. The display apparatus of claim 2, wherein the conductive bank layer further includes a second hole arranged in the non-sub-pixel area and disposed adjacent to the first hole, and wherein a second organic material portion of the organic layer is disposed inside the second hole, wherein the first organic material portion and the second organic material portion are spaced apart from each other in a plan view.

4. The display apparatus of claim 2, wherein the first hole of the conductive bank layer passes through the conductive bank layer, and the first organic material portion is in direct contact with an upper surface of the insulating layer through the first hole.

5. The display apparatus of claim 1, wherein a bottom surface of the organic layer is in direct contact with an upper surface of the second conductive layer.

6. The display apparatus of claim 1, wherein the second conductive layer is disposed on an upper surface of the first conductive layer, and wherein the second conductive layer includes a tip protruding from a point at which a lateral surface of the first conductive layer facing the first opening meets a bottom surface of the second conductive layer.

7. The display apparatus of claim 6, further comprising:
a first dummy intermediate layer disposed on the tip and including a same material as a material of the first intermediate layer; and
a first dummy opposite electrode disposed on the first dummy intermediate layer and including a same material as a material of the first opposite electrode.

8. The display apparatus of claim 1, wherein the organic layer includes an organic insulating material.

9. The display apparatus of claim 8, wherein the organic layer includes black pigment.

10. A display apparatus comprising:
a first sub-pixel electrode and a second sub-pixel electrode disposed adjacent to each other;
a conductive bank layer including a first opening overlapping the first sub-pixel electrode, and a second opening overlapping the second sub-pixel electrode, and including a first conductive layer and a second conductive layer disposed on the first conductive layer;
a first intermediate layer disposed on the first sub-pixel electrode;
a first opposite electrode disposed on the first intermediate layer;
a second intermediate layer disposed on the second sub-pixel electrode;
a second opposite electrode disposed on the second intermediate layer;
an insulating layer overlapping an edge of the first sub-pixel electrode and an edge of the second sub-pixel electrode and disposed under the conductive bank layer in a non-sub-pixel area between the first sub-pixel electrode and the second sub-pixel electrode; and
an organic layer including a first organic layer opening overlapping the first opening, a second organic layer opening overlapping the second opening, and a first organic material portion arranged in the non-sub-pixel area.

11. The display apparatus of claim 10, wherein the conductive bank layer includes a first hole arranged in the non-sub-pixel area, wherein at least a portion of the first organic material portion is disposed inside the first hole.

12. The display apparatus of claim 10, wherein a bottom surface of the organic layer is in direct contact with an upper surface of the second conductive layer.

13. The display apparatus of claim 11, wherein a depth of the first hole is less than a thickness of the conductive bank layer.

14. The display apparatus of claim 11, wherein a depth of the first hole is equal to a thickness of the conductive bank layer, and wherein at least a portion of the organic material portion is in direct contact with an upper surface of the insulating layer.

15. The display apparatus of claim 10, wherein a first portion of the second conductive layer includes a tip protruding to the first opening from a point at which a lateral surface of the first conductive layer facing the first opening meets a bottom surface of the second conductive layer, and
a second portion of the second conductive layer includes a tip protruding to the second opening from a point at which a lateral surface of the first conductive layer facing the second opening meets a bottom surface of the second conductive layer.

16. The display apparatus of claim 15, further comprising:
a first dummy intermediate layer formed on the tip protruding to the first opening and including a same material as a material of the first intermediate layer;
a first dummy opposite electrode formed on the first dummy intermediate layer and including a same material as a material of the first opposite electrode;
a second dummy intermediate layer formed on the tip protruding to the second opening and including a same material as a material of the second intermediate layer; and
a second dummy opposite electrode formed on the second dummy intermediate layer and including a same material as a material of the second opposite electrode.

17. The display apparatus of claim 11, wherein the conductive bank layer further includes a second hole disposed adjacent to the first hole, wherein the first hole is spatially separated from the second hole.

18. The display apparatus of claim 17, wherein the organic layer further includes a second organic material portion, wherein at least a portion of the second organic material portion is disposed inside the second hole, and
wherein the first organic material portion and the second organic material portion are spaced apart from each other.

19. The display apparatus of claim 10, wherein the organic layer includes an organic insulating material.

20. The display apparatus of claim 19, wherein the organic layer includes black pigment.
